(19) United States
(12) Patent Application Publication
(10) Pub. No.: US 2018/0067402 A1
(43) Pub. Date: Mar. 8, 2018

(54) EXPOSURE APPARATUS AND COMPUTER READABLE NON-TRANSITORY STORAGE MEDIUM

(71) Applicant: ADVANTEST CORPORATION, Tokyo (JP)

(72) Inventors: Akio YAMADA, Saitama (JP); Tatsuro OKAWA, Saitama (JP); Masaki KUROKAWA, Saitama (JP)

(21) Appl. No.: 15/786,603

(22) Filed: Oct. 18, 2017

Related U.S. Application Data
(63) Continuation of application No. PCT/JP2017/018035, filed on May 12, 2017.

(30) Foreign Application Priority Data
Sep. 6, 2016 (JP) 2016-173564

(51) Int. Cl. G03F 7/20

(52) U.S. Cl. CPC G03F 7/70508; G03F 7/7005

(57) ABSTRACT

An exposure apparatus including a plurality of column units to generate a plurality of charged particle beams arrayed in a first direction, a column control unit to separately control irradiation timings of the charged particle beams, a converting unit to convert design data describing an arrangement coordinate of device patterns as a base into exposure data including second data which is divided into belt-like regions having a width of one charged particle beam and extending in a second direction, and first data which specifies the second data based on a position of the first direction, a first storing unit to store the exposure data, and a distributing unit to distribute each of the column units by reconfiguring the exposure data in accordance with an exposure order, and a method of creating exposure data structure and beam control data for such an exposure apparatus are provided.

The contents of the following Japanese patent application(s) are incorporated herein by reference:
NO. 2016-173564 filed on Sep. 6, 2016, and
NO. PCT/JP2017/18035 filed on May 12, 2017.

### BACKGROUND

### 1. Technical Field

The present invention is related to an exposure apparatus and a non-transitory storage medium which records an exposure data structure and is readable by a computer.

### 2. Related Art

Conventionally, a complementary lithography has been known, which forms a fine circuit pattern by processing a simple line pattern formed by using an exposure technology of light having a line width of about 10 nm according to an exposure technology using charged particle beams such as electron beams to (for example, refer to Patent Document 1). Also, a multi-beam exposure technology using a plurality of charged particle beams has also been known (for example, refer to Patent Document 2). Further, a multi-column exposure technology including a plurality of charged particle columns has also been known (for example, refer to Patent Document 3).

### PRIOR ART LITERATURE

### Patent Document

[Patent Document 1] Japanese Patent Application Publication No. 2013-157547

[Patent Document 2] Japanese Patent Application Publication No. 2015-133400

[Patent Document 3] Japanese Patent Application Publication No. 2015-012035

In the complementary lithography, a pattern that the charged particle beams expose is limited by its position, size and the like in order to combine with a line pattern. Based on such a limitation, design data of a device describes coordinate values of vertex positions of individual device patterns based on a coordinate system set in the device, for example. The data layout of the design data of the device depends on a design tool used for the design of the device, and does not necessarily reflect an exposure order according to the exposure apparatus. It has been difficult to create control data which separately controls a plurality of charged particle beams of a plurality of charged particle columns from the design data of the device.

### SUMMARY

Here, in one aspect of a technical innovation included in the present specification, the purpose is to provide an exposure apparatus and an exposure data structure which can solve the above-described issue. This purpose is achieved by combinations of features according to the claims. That is, in a first embodiment of the present invention, an exposure apparatus is provided, which irradiates a plurality of charged particle beams arrayed in a first direction orthogonal to a longitudinal direction of a line pattern to form a cut pattern on a sample on which the line pattern has been formed while moving the sample in a second direction being the longitudinal direction of the line pattern formed in advance on the sample, and the exposure apparatus includes a plurality of column units to generate a plurality of charged particle beams arrayed in the first direction, a column control unit to separately control irradiation timings of the charged particle beams, a converting unit to convert design data describing an arrangement coordinate of device patterns as a base into exposure data including second data which is divided in a belt-like region having a width of one charged particle beam and extending in a second direction and first data which specifies the second data based on a position of a first direction, a first storing unit to store the exposure data, and a distributing unit to distribute each of the column units by reconfiguring the exposure data in accordance with an exposure order.

In a second embodiment of the present invention, an exposure data structure for an exposure apparatus is provided, the exposure data structure configured with subgrid data to designate an arrangement coordinate of patterns included in subgrids having a fixed length in a second direction among patterns included in grids having a width the same as a minimum width of a line pattern and extending in the second direction, grid data to designate subgrid data included in one piece of grid, and grid group data to designate the grid data belonging to a grid group divided in a first direction for each fixed range.

In a third embodiment of the present invention, a method of converting design data describing an arrangement coordinate of device patterns into exposure data, and a method of reconfiguring the exposure data in accordance with an exposure order of a column unit and then distributing the exposure data as beam control data which controls charged particle beams of the column unit, are provided.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows a configuration example of an exposure apparatus 100 according to the present embodiment.

FIG. 2 shows one example of an irradiation possible region 200 formed on a part of a surface of a sample 10 by scanning an array beam by the exposure apparatus 100 according to the present embodiment.

FIG. 3 shows one example of an operation of scanning an array beam 500 to expose patterns 410, 420, and 430 by the exposure apparatus 100 according to the present embodiment.

FIG. 4 shows one example of an exposure pattern 610 included in a device 600.

FIG. 5 shows one example that the exposure pattern 610 is associated with a grid structure.

FIG. 6 shows a configuration example of first data 164 which configures exposure data 162.

FIG. 7 shows a configuration example of second data 166 which configures the exposure data 162.

FIG. 8 shows an example of a converting flow of creating the exposure data 162 from design data 150.

FIG. 9 shows an example of a positional relation among a plurality of devices 600 arranged on the sample 10 and the irradiation possible region 200.

FIG. 10 shows a configuration example of beam control data 184.

FIG. 11 shows an example of an exposure flow showing a part of frame exposure.

FIG. 12 shows a configuration example of history data 194.

### DESCRIPTION OF EXEMPLARY EMBODIMENTS

The embodiments do not limit the invention according to the claims, and all the combinations of the features described in the embodiments are not necessarily essential to means provided by aspects of the invention.

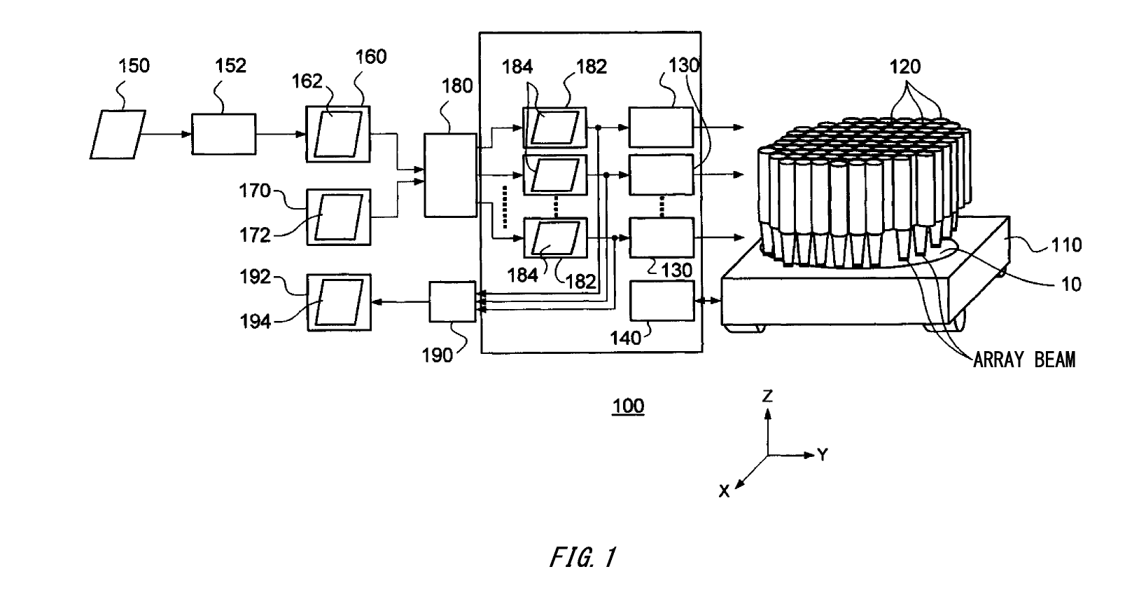

FIG. 1 shows a configuration example of an exposure apparatus 100 according to the present embodiment. The exposure apparatus 100 irradiates, on a position according to a line pattern formed on a sample based on a predetermined grid, a charged particle beam having an irradiation region corresponding to the grid to form a device pattern such as a cut pattern or a via pattern.

The exposure apparatus 100 includes one stage portion 110 and a plurality of column units 120 on the side near the sample 10 shown in FIG. 1. Also, the exposure apparatus 100 includes one stage control unit 140 and a plurality of column control units 130 in order to control the one stage portion 110 and the plurality of column units 120. Each of the plurality of column control units 130 separately controls the corresponding column unit 120. The stage control unit 140 detects a position of the stage portion 110, and controls a movement of the stage portion 110 based on a detection result of the position of the stage portion 110.

The sample 10 placed on the stage portion 110 is, as one example, a semiconductor wafer formed of silicon and the like, and a plurality of line patterns of conductors such as metal are formed in parallel with each other on its surface. The exposure apparatus 100 according to the present embodiment irradiates the charged particle beam on a resist coated on the line patterns in order to perform a fine processing (forming an electrode or a wiring by cutting, and/or forming a contact by a via hole) on the line pattern. In the following specification, it is described that a first direction controlling the exposure apparatus 100 represents a direction orthogonal to a longitudinal direction of the line patterns, and the second direction controlling the exposure apparatus 100 represents the longitudinal direction of the line patterns.

The sample 10 is placed on the stage portion 110 on a XY plane shown in FIG. 1 so that the longitudinal direction of the line patterns formed on the surface of the sample 10 is approximately in parallel with an X-axis direction. Also, the stage portion 110 moves in the X-axis direction during the exposure. Accordingly, the stage portion 110 during the exposure moves the sample 10 in a direction approximately parallel with the longitudinal direction of the line pattern formed on the surface of the sample 10.

Each of the plurality of column units 120 generates charged particle beams having electrons, ions, or the like to irradiate the charged particle beams on the sample 10 placed on the stage portion 110. In the present embodiment, an example that the column units 120 generate electron beams is described. A number of the column units 120 is 88, as one example. The plurality of column units 120 are arranged by a pitch of approximately 30 mm on the XY plane, for example. The surface of the sample 10 that is a semiconductor wafer having a diameter of approximately 300 mm placed on the stage portion 110 is irradiated by the electron beam generated by at least one column unit 120 in a movable range of the stage portion 110.

Each of the plurality of column units 120 generates an array beam consisting of a plurality of electron beams arrayed in a row at fixed intervals. Each of the column units 120 is arranged around a Z axis so that an array direction of the array beam approximately matches a direction orthogonal to a movement direction of the stage portion 110 during the exposure. Because the sample 10 is placed on the stage portion 110 so that the movement direction of the stage portion 110 approximately matches the longitudinal direction of the line pattern formed on the surface of the sample 10 during the exposure, each of the column units 120 generates an array beam consisting of a plurality of electron beams having different irradiating positions in a width direction of the line pattern orthogonal to the longitudinal direction of the line pattern.

The beam width of the entire array beam is 60 μm, for example. A number of the electron beams included in the array beam is 4098, for example. The exposure apparatus 100 separately switches whether to irradiate each of the plurality of electron beams having different irradiating positions in the width direction of the line pattern on the sample 10 (ON state) or not (OFF state) while moving the array beam in the longitudinal direction of the line pattern to expose the pattern on the sample 10.

The exposure apparatus 100 includes a central processing unit (CPU) which integrates and controls the entire exposure apparatus 100, and a bus for transmitting and receiving instructions or data between the central processing unit and each unit configuring the apparatus, although this is not explicitly described in FIG. 1. The central processing unit is, for example, a workstation, and also has a terminal function of inputting an operation instruction from a user.

Next, a configuration of the exposure apparatus 100 in accordance with a processing flow of the exposure data from the left side toward the right side of FIG. 1 is described. The design data 150 is data of the device pattern input into the exposure apparatus 100. The design data 150 is data showing a position, size, and/or shape of the device pattern designed by using a CAD (Computer-Aided Design) tool. The design data 150 is a coordinate system set in the device, and, as one example, is one describing an arrangement coordinate of the device patterns being coordinate values of vertex positions of individual device patterns.

The design data 150 input in the exposure apparatus 100 is converted into exposure data 162 by a converting unit 152. The converting unit 152 is a data conversion apparatus which performs data conversion from the design data 150 to the exposure data 162. Also, the converting unit 152 may also be software having a data conversion function from the design data 150 to the exposure data 162. Although the exposure data 162 is data representing contents of the patterns equivalent to the design data 150, the exposure data 162 is data converted into an appropriate data format for configuring the beam control data of the exposure apparatus 100 according to the present embodiment.

The exposure data 162 is configured with first data which designates exposure data in a first direction orthogonal to a longitudinal direction of the line pattern, and second data which designates exposure data in a second direction parallel with the longitudinal direction of the line pattern. The first data designates the exposure data in a direction in which the array beam is arrayed. The second data designates the exposure data in a direction in which the stage portion 110 moves during the exposure. The first data and the second data are both data corresponding to directions which are characteristic in exposure operations of the exposure apparatus 100.

The first data and the second data have hierarchical structures inside the data, and data which designates a relatively large region of the device designates a relatively small region included therein. The exposure data 162 is created prior to the exposure, and is stored in a first storing unit 160 of the exposure apparatus 100. A configuration example of the exposure data 162 and an example of a method of creating the exposure data 162 by the converting unit 152 are described below in the later part of the present specification.

Arrangement data 172 shown in FIG. 1 is also determined prior to the exposure and is stored in an arrangement data storing unit 170 of the exposure apparatus 100. The arrangement data 172 is data related to a size of a device formed on the surface of the sample 10, an arrangement pitch of the device, an arrangement position of the device, and the like. The arrangement data 172 is determined in accordance with the design data 150 of the device and an effective exposure range and the like of the surface of the semiconductor wafer that is the sample 10. Note that because a data capacity of the arrangement data 172 is sufficiently small compared to a data capacity of the exposure data 162, the exposure apparatus 100 may not include the arrangement data storing unit 170 dedicated to the arrangement data 172. The arrangement data 172 may also be stored in a storage unit of the central processing unit (CPU), for example.

A distributing unit 180 determines a position of the exposure data 162 of the device based on the arrangement data 172 so that the position of the pattern on the sample 10 is determined. Then, the distributing unit 180 uses the arrangement data 172 of the above-described device, a measurement result of a positional relation between the sample 10 and the electron beam generated by each of the plurality of column units 120 and the like to create beam control data 184 for each of the plurality of column units 120 from the exposure data 162. The distributing unit 180 creates the beam control data 184 for each of the column units 120 by extracting, from the above-described first data and second data configuring the exposure data 162, and reconfiguring the data of the portion overlapping the irradiation possible region of each column unit 120 in accordance with an exposure order. Corresponding to the exposures of different patterns on different positions of the surface of the sample 10 performed at almost the same time by the plurality of column units 120, the distributing unit 180 distributes different beam control data 184 for the respective column units 120. Note that the first data and the second data do not directly include position coordinate data of individual patterns, and are ones defined as pointers which call a data group of patterns included in a predetermined region which is described below. Accordingly, the beam control data 184 can be created at higher speed than created by directly collecting and reconfiguring the position coordinate data of the patterns.

The beam control data 184 distributed by each of the column units 120 is stored in a second storing unit 182 corresponding to each of the column units 120. The second storing unit 182 may acquire and store in advance all of the beam control data 184 for the sample 10 prior to the exposure. Instead of this, the second storing unit 182 may also temporarily store the beam control data 184 for a partial region on the sample 10 on which each column unit 120 exposes. If the beam control data 184 is temporarily stored, each of the second storing units 182 may include at least two storing portions. The two storing portions may alternately store the beam control data 184 for two regions on the sample 10 on which each of the column units 120 continuously exposes (corresponding to two frames described below).

During a period when one of the storing portions of the second storing unit 182 temporarily stores the beam control data 184 of a first frame that is a region on which each of the column units 120 exposes by one stage movement toward the X-axis direction and outputs the beam control data 184 to the column control unit 130 to expose, the other one of the storing portions of the second storing unit 182 may receive and read, from the distributing unit 180, the beam control data 184 for a second frame that is a region exposed by a next stage movement of the column unit 120 toward the X-axis direction.

If the beam control data 184 for the partial region of the sample 10 is temporarily stored, the data capacity to store in the second storing unit 182 is reduced compared to a case where the beam control data 184 for all the sample 10 is acquired and stored in advance. A configuration example of the beam control data 184 and an example of a method of creating the beam control data 184 by the distributing unit 180 are described below in the later part of the present specification. The column control unit 130 outputs the electron beam for a fixed time to perform the exposure of the patterns at a timing when the irradiating position arrives at the designated position according to the beam control data 184 output from the second storing unit 182.

A collecting unit 190 collects history data 194 for each of the column units 120 from a connecting unit between the second storing unit 182 and the column control unit 130. The collecting unit 190 collects a part of the beam control data 184 output from the second storing unit 182 to the column control unit 130 in accordance with an order in which each of the column units exposes. The collecting unit 190 makes the history data 194 to correspond to each of the plurality of column units 120 and stores the collected history data 194 in a third storing unit 192. The history data 194 stored in the third storing unit 192 is data that records, during the exposure, which column unit 120 has exposed and in what order the column unit 120 has exposed for the pattern exposed on the surface of the sample 10. A configuration example of the history data 194 is described below in the later part of the present specification.

As described above, the exposure apparatus 100 shown in FIG. 1 includes a configuration from an input unit for the design data 150 to the stage portion 110 which performs the exposure operation via the converting unit 152, and the column unit 120. Instead of this, the exposure apparatus 100 may also have a configuration without the converting unit 152. In this case, the exposure apparatus 100 may be set to have a configuration from the first storing unit 160 which stores the exposure data 162 to the stage portion 110 which performs the exposure operation, and the column unit 120. In the latter case, the converting unit 152 may be arranged by separating from the exposure apparatus 100. The converting unit 152 converts the design data 150 into the exposure data 162 prior to the exposure during an appropriate time period after the design data 150 is created in a designing process of the device. In this case, the converting unit 152 may have been connected to a local area network (LAN) of a facility in which the exposure apparatus 100 is arranged and transfer the exposure data 162 to the first storing unit 160 of the exposure apparatus 100 via the local area network, for example.

Next, before describing a configuration example and an example of the creating method of the exposure data 162, a configuration example and an example of the creating method of the beam control data 184, a configuration example of the history data 194, and the like, the exposure operation of the column unit 120 is described, which is a prerequisite to the above.

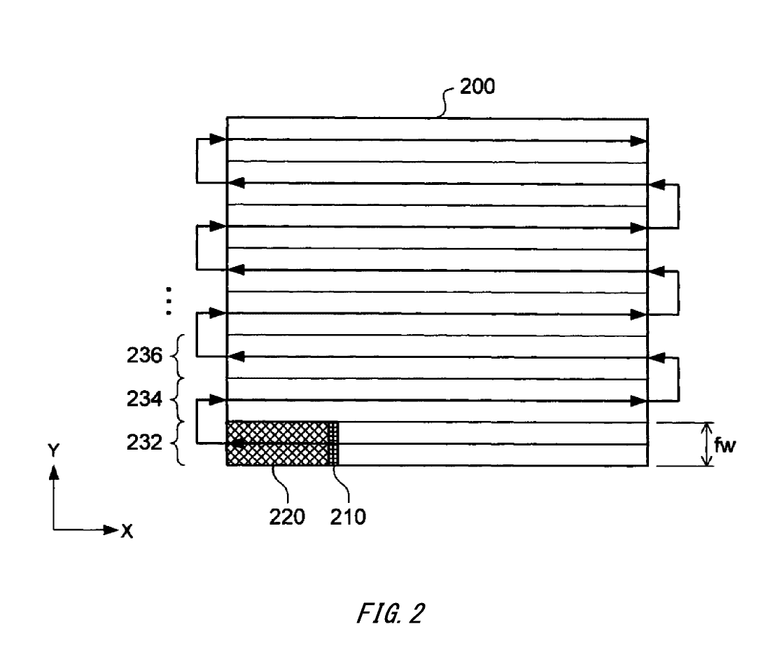

FIG. 2 shows one example of an irradiation possible region 200 formed on a part of the surface of the sample 10 by scanning, by the exposure apparatus 100 according to the present embodiment, an array beam output from one column unit 120. An example is shown that the stage control unit 140 moves the stage portion 110 in the X-axis direction approximately parallel with the second direction which is the longitudinal direction of the line pattern. That is, prior to the exposure, the sample 10 is arranged aligning the longitudinal direction of the line pattern with the X-axis direction which is a continuous movement direction of the stage portion 110. Here, the stage portion 110 can move the sample 10 while keeping an extremely high position accuracy and speed stability for the continuous movement direction under the control of the stage control unit 140.

An irradiating position 210 of an array beam generated by one column unit 120 is a region elongatedly extending in the Y-axis direction as illustrated. The irradiating position 210 moves in the +X direction on the surface of the sample 10 along with the movement of the stage portion 110. Accordingly, the array beam irradiates a belt-like region 220 with the electron beam. The stage control unit 140 moves the stage portion 110 in the −X direction by a predetermined distance to make a first frame 232 as the irradiation possible region. The first frame 232 has a length of 30 mm in the X-axis direction that is the movement direction of the stage portion 110 and a width (fw) of 60 μm in the Y-axis direction that is the beam width direction of the array beam, and has an area of 30 mm×60 μm, as one example.

The stage control unit 140 then moves the stage portion 110 in the −Y direction by the beam width of the array beam (the width shown as fw in FIG. 2), and further moves the stage portion 110 in the +X direction so as to move back the stage portion 110. Accordingly, the irradiating position 210 of the array beam moves on the surface of the sample 10 in the −X direction through a path different from the first frame 232 to irradiate the beam on a second frame 234 which has approximately the same area as that of the first frame 232 and is adjacent to the first frame 232 in the +Y direction. Similarly, the stage control unit 140 moves the stage portion 110 in the −Y direction by the beam width of the array beam, and moves again the stage portion 110 in the −X direction by the predetermined distance to irradiate the beam on a third frame 236.

The stage control unit 140 reciprocates the stage portion 110 in the X-axis direction approximately parallel with the second direction that is the longitudinal direction of the line pattern to irradiate the beam, by one column unit 120, on the irradiation possible region 200 that is a predetermined region on the surface of the sample 10. The irradiation possible region 200 can be taken as a square-shape region of approximately 30×30 mm, for example. Although the size of this irradiation possible region 200 is determined by the control operation of the stage control unit 140, it is suitable to set the size to be approximately the same as the arrangement interval of the column unit 120 because the exposure can be performed on the entire surface of the sample 10 by performing the exposure simultaneously and concurrently with all of the column units 120.

Each column unit 120 and the column control unit 130 which controls the column unit 120 progress the exposure per frame. That is, the column control unit 130 performs the exposure on the first frame 232 by acquiring the beam control data 184 for the first frame 232 temporarily stored in one of the storing portions of the second storing unit 182 connected to the column control unit 130 and controlling the column unit 120. During a period when the column control unit 130 controls the exposure operation for the first frame 232, the other one of the storing portions of the second storing unit 182 of the same column unit 120 receives the beam control data 184 for the second frame 234 from the distributing unit 180 and stores the beam control data 184.

During a period when the column control unit 130 controls the exposure operation for the second frame 234, one of the storing portions of the second storing unit 182 of the same column unit 120 receives the beam control data 184 for the third frame 236 from the distributing unit 180 and stores beam control data 184. The one of the storing portions and the other one of the storing portions of the second storing unit 182 repetitively input and output the beam control data 184 for at least two frames so that the column unit 120 and the column control unit 130 progress the exposure operation for the plurality of frames without interruption.

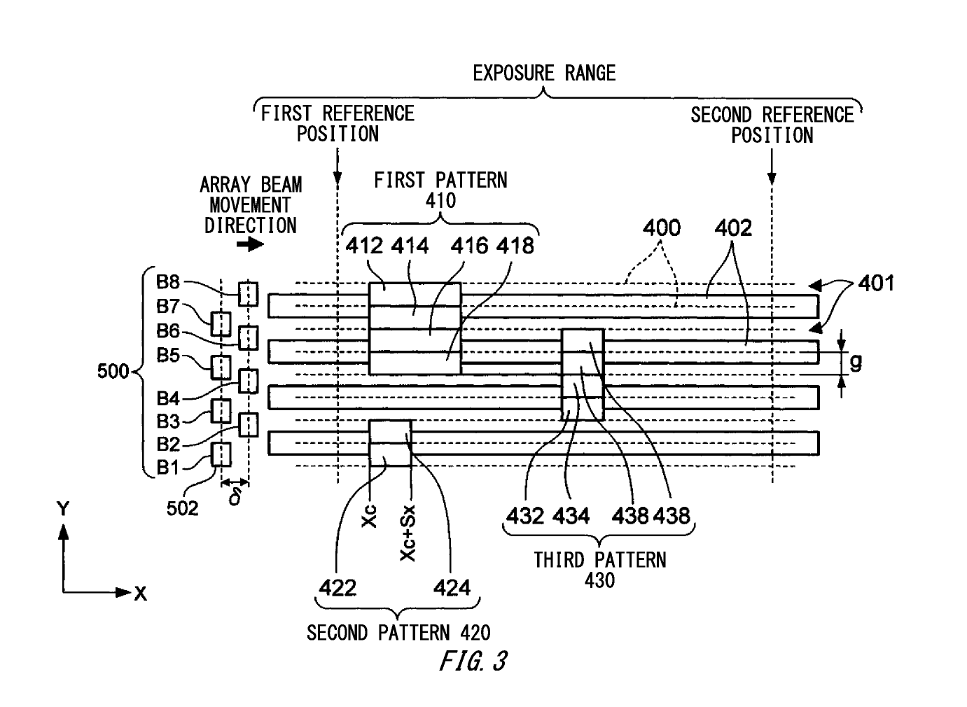

FIG. 3 is a drawing showing more detail of the operation that the array beam output from one column unit 120 exposes the cut pattern included in one frame in FIG. 2. In FIG. 3, the second direction that is the longitudinal direction of the line pattern is the X-axis direction, and the first direction that is the direction orthogonal to the longitudinal direction of the line pattern is the Y-axis direction.

A plurality of dashed lines being in parallel with the X-axis direction and having an interval g therebetween in the Y-axis direction is referred to as grid lines 400. A section which is held between the grid lines 400, has a width g in the Y-axis direction, and is elongated in the X-axis direction is referred to as a grid 401. The width g is a grid width. Also, a line pattern 402 formed in advance on the surface of the sample 10 has a longitudinal direction matching the X-axis direction that is the longitudinal direction of the grid 401. The minimum value of the Y-axis direction width of the line pattern 402 is approximately equal to the grid width g.

The pattern that the exposure apparatus 100 according to the present embodiment exposes is designed based on the grid lines 400 and the grid 401. In FIG. 3, the rectangles described as a first pattern 410, a second pattern 420, and a third pattern 430 show examples of the exposure pattern. Values of integer multiples (1 or greater than 1) of the grid width g are used for the length of the exposure pattern in the Y-axis direction and the interval between the patterns in the Y-axis direction.

For example, the length of the first pattern 410 in the Y-axis direction in FIG. 3 is approximately equal to 4 g, the length of the second pattern 420 in the Y-axis direction is approximately equal to 2 g, and the length of the third pattern 430 in the Y-axis direction is approximately equal to 4 g. Also, the pattern interval between the first pattern 410 and the second pattern 420 in the Y-axis direction is approximately equal to 2 g.

Also, the exposure pattern may be arranged so that the Y-coordinate value in the first direction approximately matches the Y-coordinate value of the grid line 400 in the first direction. For example, the Y-coordinate value on a lower end (the end in the −Y direction) of the first pattern 410 approximately matches the Y-coordinate value of the grid line which is fifth counted from the grid line on the lowermost end in the drawing, and the Y-coordinate value on an upper end (the end of the +Y direction) of the first pattern 410 approximately matches the Y-coordinate value of the grid line which is ninth counted from the grid line on the lowermost end. The Y-coordinate value on a lower end of the second pattern 420 approximately matches the Y-coordinate value of the grid line on the lowermost end, and the Y-coordinate value on an upper end of the second pattern 420 approximately matches the Y-coordinate value of the grid line which is third counted from the grid line on the lowermost end.

FIG. 3 is an XY-plane view showing one example of a positional relation among the line pattern 402 formed in advance on the surface of the sample 10, and the first pattern 410, the second pattern 420, and the third pattern 430 which are examples of the exposure pattern. The first pattern 410 is a pattern in which two pieces of the line patterns 402 are simultaneously cut from the uppermost portion, the second pattern 420 is a pattern in which the line pattern 402 in the lowermost portion is cut, and the third pattern 430 is a pattern in which two pieces of the line patterns 402 in the center are simultaneously cut.

FIG. 3 is also an XY-plane view showing one example of a positional relation between the line pattern 402 formed in advance on the surface of the sample 10 and an irradiation region 502 of an array beam 500 output from one column unit 120. The column unit 120 generates a first group of electron beams (for example, a group of electron beams corresponding to a row of the irradiation regions 502 on the left side) which is arrayed in a row at fixed intervals in the Y axis that is the first direction, and a second group of electron beams (for example, a group of electron beams corresponding to a row of the irradiation regions 502 on the right side) which is arranged adjacent to the first group of electron beams apart therefrom by a distance 6 in parallel with the X-axis direction and arranged with the same size and by the same pitch as those of the first group of electron beams.

An example of a case where the irradiation regions 502 of the array beam 500 output from the column unit 120 have moved to a starting point of a frame (the end portion on the −X direction side of the frame) is shown. The array beam 500 output from the column unit 120 moves on the surface of the sample 10 along with the movement of the stage portion 110 to form the frame. In the drawing, an example is shown that the frame has four pieces of line patterns 402, and the line width of each line pattern 402 and the interval between the adjacent line patterns 402 are both approximately equal to the grid width g.

As the array beam 500, total 8 electron beams B1 to B8 are shown. B1, B3, B5, and B7 belong to the first group of electron beams, and B2, B4, B6, and B8 belong to the second group of electron beams. The array beam 500 irradiates the electron beams on each of the plurality of the irradiation regions 502. Each of the beam widths of the electron beams B1 to B8 in the Y-axis direction is approximately equal to the grid width g. Also, the irradiating positions of the electron beams B1 to B8 are respectively arrayed in the Y-axis direction shifting each other by the grid width g. The array beam 500 exposes with a beam width of approximately 8 g as a whole.

The irradiation regions 502 of the plurality of electron beams included in the array beam 500 respectively move on the corresponding grids 401 along with the continuous movement of the stage portion 110. In the illustrated example, an example is shown that the irradiation region of the electron beam B1 moves on the grid which is first from the −Y direction side, and the irradiating position of the electron beam B2 moves on the grid which is second from the −Y direction side.

The column control unit 130 detects the Y coordinate values of the exposure pattern in the first direction based on the beam control data 184 acquired from the second storing unit 182. The column control unit 130 selects the electron beam used for the exposure in accordance with the Y-coordinate value of the pattern. The second pattern 420 of FIG. 3 is described as an example. In accordance with the Y-coordinate value of the second pattern 420 detected based on the beam control data 184 being in the range from the first grid 401 to the second grid 401 on the −Y direction side, the column control unit 130 selects the electron beams B1 and B2 which have the irradiation regions being in the range of the Y-coordinate values. The electron beam B1 is used for exposing a pattern 422 that is a part of the second pattern 420, and the electron beam B2 is used for exposing a pattern 424 that is a part of the second pattern 420.

Also, the column control unit 130 detects the X-coordinate values in the second direction of the exposure pattern based on the beam control data 184 acquired from the second storing unit 182. The column control unit 130 sets an irradiation timing of switching the electron beam to an ON state or OFF state in accordance with the X-coordinate value of the pattern for each of the electron beams included in the first group of electron beams and the second group of electron beams which configure the irradiation region 502 of FIG. 3.

That is, the column control unit 130 uses the X-coordinate value of the pattern in the second direction, the X-coordinate value of a reference position (refer to FIG. 3) preset in the longitudinal direction of the line pattern, and the movement speed of the stage portion 110 to set an elapsed time from the time when the irradiation region 502 of the array beam 500 passes through the reference position to the time when arriving at the X-coordinate value of the pattern. The column control unit 130 acquires, from the stage control unit 140, the timing when the irradiation region 502 of the array beam 500 passes through the reference position. The column control unit 130 switches between the ON/OFF states of the corresponding electron beam after the elapsed time from the time point when passing through the reference position.

The second pattern 420 of FIG. 3 is described as an example. The column control unit 130 detects the X-coordinate values Xc and Xc+Sx on both ends of the second pattern 420 based on the beam control data 184 of the second storing unit 182. The irradiation region 502 of the array beam 500 is scanned, due to the movement of the stage portion 110, at a predetermined speed in the +X direction or the −X direction being the longitudinal direction of the line pattern.

If the stage portion 110 moves the irradiation region 502 in the +X direction, the column control unit 130 sets the elapsed time from the time when the stage portion 110 is at the first reference position of FIG. 3 to the time when the stage portion 110 arrives at the X-coordinate value Xc of the second pattern 420, and the elapsed time from the time when the stage portion 110 is at the first reference position to the time when the stage portion 110 arrives at the X-coordinate value Xc+Sx of the second pattern 420. The column control unit 130 obtains, from the stage control unit 140, the timing when the irradiation region 502 of the array beam 500 passes through the first reference position, and switches the electron beams B1 and B2 from the OFF state to the ON state after the elapsed time when arriving at the X-coordinate value Xc. The column control unit 130 switches the electron beams B1 and B2 from the ON state to the OFF state after the elapsed time when arriving at the X-coordinate value Xc+Sx. Accordingly, the electron beam is irradiated within the range of the second pattern 420 in the longitudinal direction of the line pattern.

If the stage portion 110 moves the irradiation region 502 in the −X direction, the column control unit 130 sets the elapsed time from the time when the stage portion 110 is at the second reference position of FIG. 3 to the time when the stage portion 110 arrives at the X-coordinate value Xc+Sx of the second pattern, and the elapsed time from the time when the stage portion 110 is at the second reference position to the time when the stage portion 110 arrives at the X-coordinate value Xc of the second pattern. The column control unit 130 obtains, from the stage control unit 140, the timing when the irradiation region 502 of the array beam 500 passes through the second reference position, and switches the electron beams B1 and B2 from the OFF state to the ON state after the elapsed time when arriving at the X-coordinate value Xc+Sx. The column control unit 130 switches the electron beams B1 and B2 from the ON state to the OFF state after the elapsed time when arriving at the X-coordinate value Xc. Accordingly, the electron beam is irradiated within the range of the second pattern 420 in the longitudinal direction of the line pattern.

FIG. 3 has shown a case where one column unit 120 outputs the array beam which has total 8 electron beams B1 to B8. If the column unit 120 is to output an array beam which generally has n electron beams, one column unit 120 may also perform a similar exposure operation.

That is, the exposure apparatus 100 according to the present embodiment scans, in the second direction which is the longitudinal direction of the line pattern, the irradiation region of the array beam configured with the first group of electron beams and the second group of electron beams arrayed in the first direction so as to expose the pattern present in the frame having a width of nxg equivalent to the grids 401 being the first one to the n-th one. The irradiation region of the electron beam Bk (where 1≦k≦n) included in the array beam may be set so as to move on the k-th grid 401, and the column control unit 130 may select the electron beam to expose the pattern based on the Y-coordinate value of the pattern in the first direction. Also, the column control unit 130 may set the irradiation timing of switching the electron beam from the ON state to the OFF state based on the X-coordinate value of the pattern in the second direction for each of the selected electron beams.

Further, the exposure apparatus 100 according to the present embodiment includes 88 column units 120, for example. In the exposure apparatus 100, each of the 88 column units 120 performs the exposure operation shown in FIG. 2 and FIG. 3. In the exposure apparatus 100, the 88 column units 120 perform the exposure on the entire surface of the sample 10 concurrently. The exposure apparatus 100 including the 88 column units 120 exposes the entire surface of the sample 10 for a time when each of the column units 120 perform the exposure on the irradiation possible region 200 (refer to FIG. 2) which is a square of approximately 30×30 mm, for example.

Accordingly, the exposure apparatus 100 including the plurality of column units 120 can significantly improve the exposure throughput compared to an exposure apparatus including a single column unit 120. Also, even if the sample 10 is a semiconductor wafer and the like with a diameter which is a large diameter over 300 mm, the exposure apparatus 100 can prevent the throughput from being extremely lowered by increasing the number of the column units 120.

Configuration examples of the exposure data 162, the beam control data 184 and the history data 194, and an example of the method of creating the exposure data 162 and the beam control data 184 according to the present embodiment are described.

[Configuration Example of Exposure Data and Example of Exposure Data Creating Method]

A configuration example of the exposure data 162 converted from the design data 150 is described.

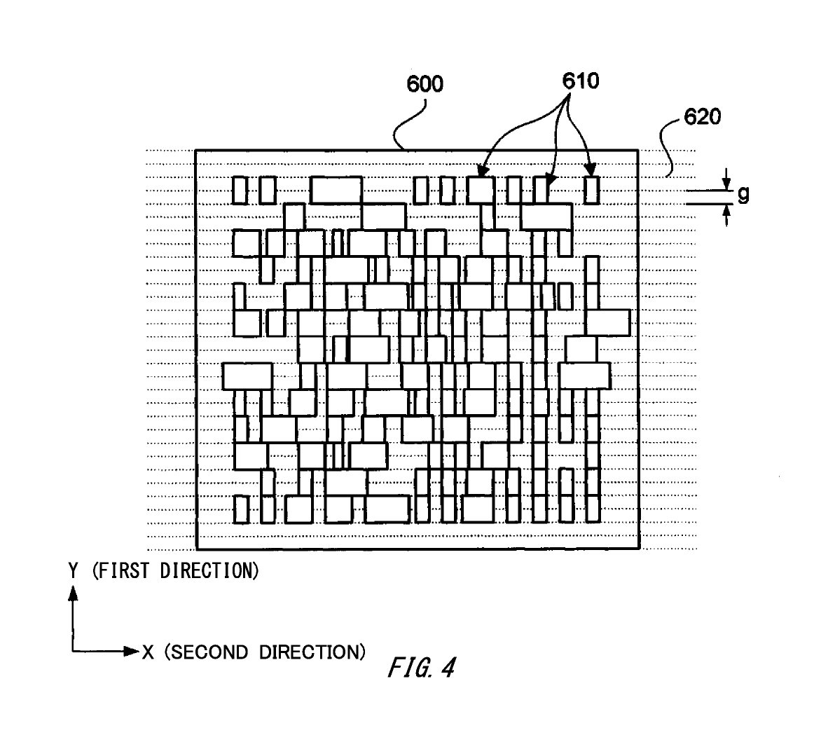

FIG. 4 shows one example of an exposure pattern 610 exposed by the exposure apparatus 100 according to the present embodiment. The exposure pattern 610 includes a plurality of rectangles arranged within a range of a device 600. The exposure pattern 610 is one example of the device pattern described by the design data 150 designed by using a CAD tool. Generally, the data layout of the design data 150 does not reflect an exposure order according to the exposure apparatus 100. For this reason, it is necessary that the exposure apparatus 100 converts the design data 150 into the control data to control the exposure apparatus 100 including the plurality of column units 120 and the plurality of electron beams. However, according to the following reasons, it is difficult to create the control data directly from the design data 150.

The first reason is that there is a data capacity issue for the design data 150. Although the data capacity of the design data 150 depends on the scale of the device 600 or a complexity of the pattern, the recent device 600 is 1 to 2 TB (terabytes), for example. It is difficult to perform, during the exposure, a process of separately reading the design data 150 having a huge capacity, and rearranging the order of the data. The second reason is the device size issue. The size of the device 600 to be exposed generally does not match the arrangement pitch of the column unit 120. For this reason, the design data 150 of the device 600 cannot be simply distributed to each of the plurality of column units 120.

On the other hand, the exposure pattern 610 applied to the complementary lithography is combined with the line pattern (the line-and-space pattern having the predetermined width and interval) so as to form a cut pattern which disconnects the line pattern or a via pattern which contacts the line pattern. For this reason, each of the rectangles configuring the exposure pattern 610 is arranged along the longitudinal direction of the line pattern. The width and the interval in the direction orthogonal to the longitudinal direction of the line pattern of each of the rectangles configuring the exposure pattern 610 become values of integer multiples of the minimum values of the width and the interval of the line pattern.

In FIG. 4, the second direction parallel with the longitudinal direction of the line pattern corresponds to the X-axis direction of the coordinate system set in the device 600. The first direction orthogonal to the longitudinal direction of the line pattern corresponds to the Y-axis direction of the coordinate system set in the device 600. A dashed line 620 is a straight line which extends in the X-axis direction and has an interval g in the Y-axis direction. The interval g between the adjacent dashed lines 620 matches the minimum width of the line pattern combined with the exposure pattern 610.

Each of the rectangles configuring the exposure pattern 610 is arrayed along the dashed line 620 in the X-axis direction. Each of the rectangles configuring the exposure pattern 610 may be arranged so that the end portion in the Y-axis direction matches the Y-coordinate value of the dashed line 620. That is, the relation between the exposure pattern 610 and the dashed lines 620 of FIG. 4 is, if enlarging a part thereof, equivalent to the relation among the patterns 410, 420 and 430, and the grid lines 400 of FIG. 3. As the dashed line 620 of FIG. 4 is made to match the grid line 400 of FIG. 3, the exposure pattern 610 of FIG. 4 and the patterns 410, 420, 430 of FIG. 3 respectively become the cut pattern which disconnects the line pattern arranged overlapping the dashed lines and the grid lines arrayed alternately in the Y-axis direction among the dashed lines 620 of FIG. 4 and the grid lines 400 of FIG. 3.

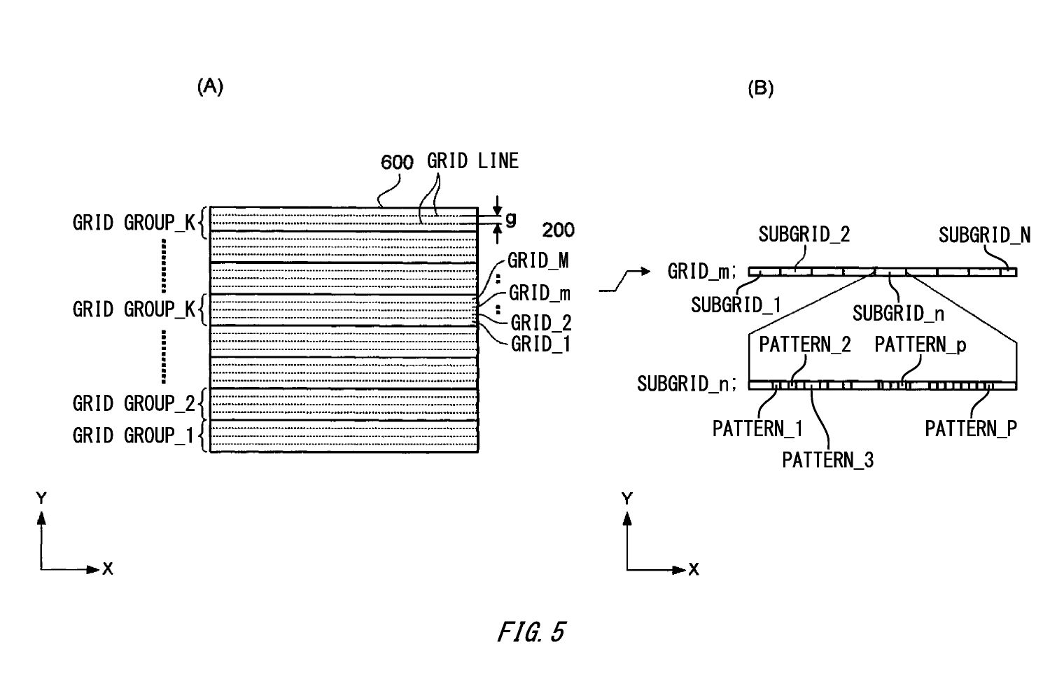

FIG. 5 shows one example that the exposure pattern 610 is associated with the grid structure based on the arrangement of the exposure pattern 610 shown in FIG. 4. The portion (A) of FIG. 5 shows that the entire area of the device 600 in the Y-axis direction is divided into a plurality of grids by grid lines. The width g of the grid in the Y-axis direction is approximately the same as the minimum width of the exposure pattern 610, and is approximately 10 nm, for example. Each grid is arrayed along the X-axis direction within the range and includes the rectangles configuring the exposure pattern 610 or at least a part thereof. That is, each grid can be associated with the exposure pattern 610 included in the grid. Note that in the present specification, it is assumed that the term “exposure pattern 610” not only means the entire pattern shown in FIG. 4 and individual rectangles configuring the entire pattern, but also means a part thereof.

The portion (A) of FIG. 5 shows an example that the plurality of grids adjacent to each other in the Y-axis direction configure a grid group. The grid group is defined as a set of 100 to 1000 adjacent grids, for example. The Y-axis direction width of the grid group is, according to the reasons shown below, 1 μm to 10 μm, for example. Gridgroup_k which is any grid group is configured with Grid_1, Grid_2, . . . , Grid_m, . . . , and Grid_M which are the plurality of grids belonging to the grid group.

Each of the exposure patterns 610 shown in FIG. 4 is included in any of Gridgroup_1, Gridgroup_2, . . . , Gridgroup_k, . . . , and Gridgroup_K in the Y-axis direction. The exposure pattern 610 of the device 600 can be associated with any of these grid groups.

On the other hand, the portion (B) of FIG. 5 shows a configuration example of the exposure pattern 610 inside the grid. The Grid_m being any grid is included in the grid and is configured with the plurality of subgrids having a predetermined length in the X-axis direction; that is, Subgrid_1, Subgrid_2, . . . , Subgrid_n, . . . , and Subgrid_N. The length of the subgrid in the X-axis direction is, according to the reason shown below, is 5 μm to 50 μm, for example.

The exposure pattern 610 inside the grid can be associated with any of these subgrids. The portion (B) of FIG. 5 shows an example that Pattern_1, Pattern_2, . . . , Pattern_p, . . . , Pattern_P being the exposure patterns 610 inside the grid are associated with the Subgrid_n.

The grid group, the grid, and the subgrid correspond to the characteristic regions according to the exposure operation of the exposure apparatus 100 according to the present embodiment. The region occupied by the plurality of grid groups continuous in the Y-axis direction being the first direction corresponds to the frame (refer to FIG. 2) having the beam width of the array beam output from the column unit 120. The individual grids configuring the grid group correspond to the region on which each of the electron beams included in the array beam can be irradiated according to the movement of the stage portion 110. The subgrid included in the grid extending in the X-axis direction being the second direction designates the exposure pattern by which the electron beams is irradiated during the movement of the stage portion 110.

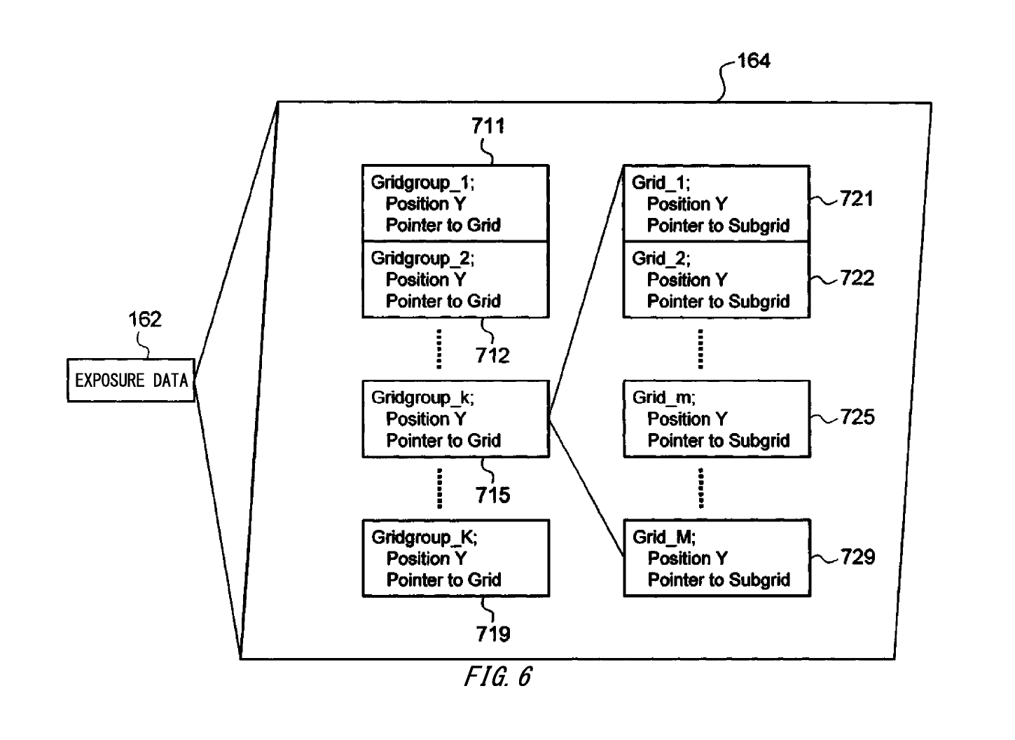

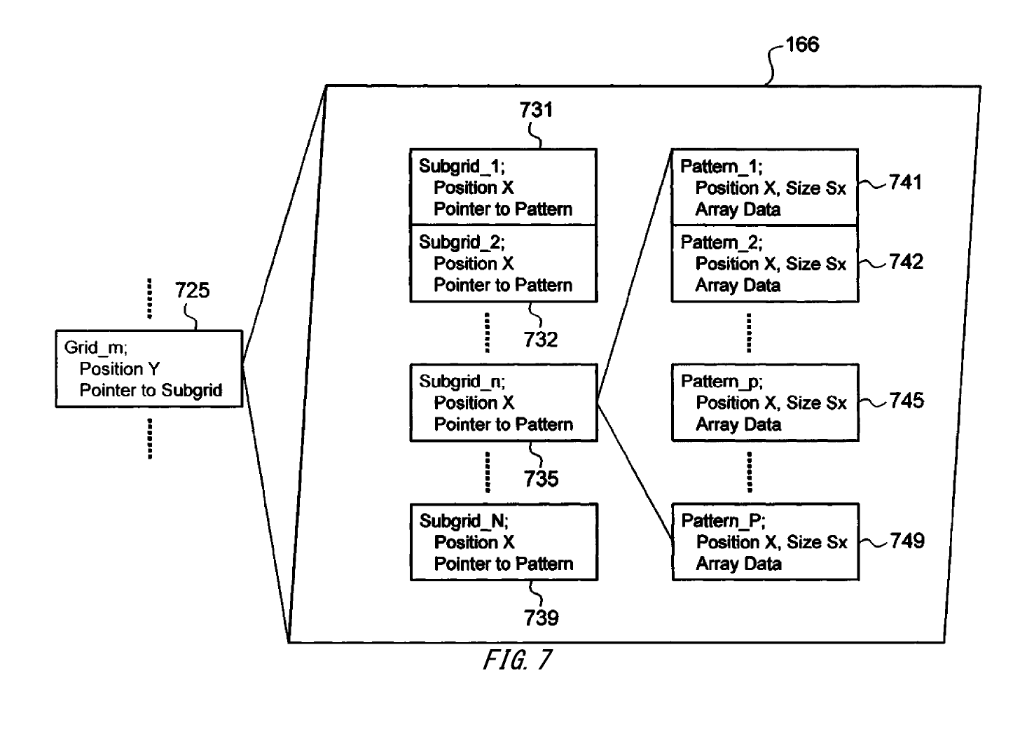

FIG. 6 and FIG. 7 show a configuration example of the exposure data 162 for the exposure apparatus 100 configured based on the relation in FIG. 5. The exposure data 162 is configured with second data 166 which has a width of one electron beam included in the array beam and is formed by dividing into the belt-like regions extending in the X-axis direction being the second direction, and first data 164 which specifies the second data 166 based on the position in the Y-axis direction being the first direction.

FIG. 6 shows a configuration example of the first data 164. The first data 164 is a grid group dividing the device 600 for each fixed range in the Y-axis direction being the first direction, corresponds to the grid group designating the plurality of grids extending in the X-axis direction being the second direction, and has grid group data, Gridgroup_1 to Gridgroup_K (reference signs 711 to 719 of FIG. 6), for example.

Data, Gridgroup_k (reference sign 715), of any Gridgroup_k has position data, Position Y, of the Gridgroup_k in the Y-axis direction in the device 600, and pointer data, Pointer to Grid, instructing the plurality of grids configuring the Gridgroup_k.

The pointer data, Pointer to Grid, of the grid group data, Gridgroup_k (the reference sign 715), designates the plurality of grid data, Grid_1 to Grid_M (reference signs 721 to 729). Accordingly, the Gridgroup_k is associated with Grid_1, Grid_2, . . . , Grid_m, . . . , Grid_M into which the Y-axis direction width of this grid group is further finely divided.

The data, Grid_m (reference sign 725), of any Grid_m has position data, Position Y, relative to Grid_m in the Y-axis direction within the Gridgroup_k, and pointer data, Pointer to Subgrid, instructing the plurality of subgrids configuring the grid_m in the X-axis direction.

FIG. 7 shows a configuration example of the second data 166. The second data is a configuration example of the exposure data included in the grid. For example, the data, Grid_m (reference sign 725 of FIG. 7), of the Grid_m designates the plurality of subgrid data, Subgrid_1 to Subgrid_N (reference signs 731 to 739) according to the pointer data, Pointer to Subgrid. Accordingly, the Grid_m is associated with the Subgrid_1, Subgrid_2, . . . , Subgrid_n, . . . , Subgrid_N which are the plurality of subgrids configuring the grid.

The data, Subgrid_n (reference sign 735), of any Subgrid_n has position data, Position X, relative to the Subgrid_n in the X-axis direction within the Grid_m and pointer data, Pointer to Pattern, instructing the plurality of patterns configuring the Subgrid_n.

The pointer data, Pointer to Pattern, of the subgrid data, Subgrid_n (reference sign 735), designates the data of the plurality of patterns, Pattern_1 to Pattern_P (reference signs 741 to 749). The subgrid data includes at least one of the data of the arrangement coordinate of the pattern included in the subgrid with a fixed length in the X-axis direction. The Subgrid_n is associated with Pattern_1, Pattern_2, . . . , Pattern_p, . . . , and Pattern_P which are the exposure patterns 610 arranged within the subgrid.

The data, Pattern_p (reference sign 745), of any Pattern_p has the position data, Position X, relative to the Pattern_p in the X-axis direction within the Subgrid_n, and size data, Sx, of the Pattern_p in the X-axis direction. Also, the data, Pattern_p (reference sign 745), may have Array Data designating a repetition of the same pattern.

That is, the exposure data 162 is configured with the first data 164 in the first direction orthogonal to the longitudinal direction of the line pattern. The first data 164 has a hierarchical structure, and has the grid group data and the grid data. Also, the exposure data 162 is configured with the second data 166 in the second direction parallel with the longitudinal direction of the line pattern. The second data 166 has the hierarchical structure, and has the subgrid data and the pattern data. The grid group data being a relatively large region designates the grid data being a relatively small region. Also, the grid data being a relatively large region designates the subgrid data being a relatively small region. Further, the subgrid data being the relatively large region designates the pattern data being the relatively small region.

An example of a method with which the converting unit 152 creates the exposure data 162 from the design data 150 is described.

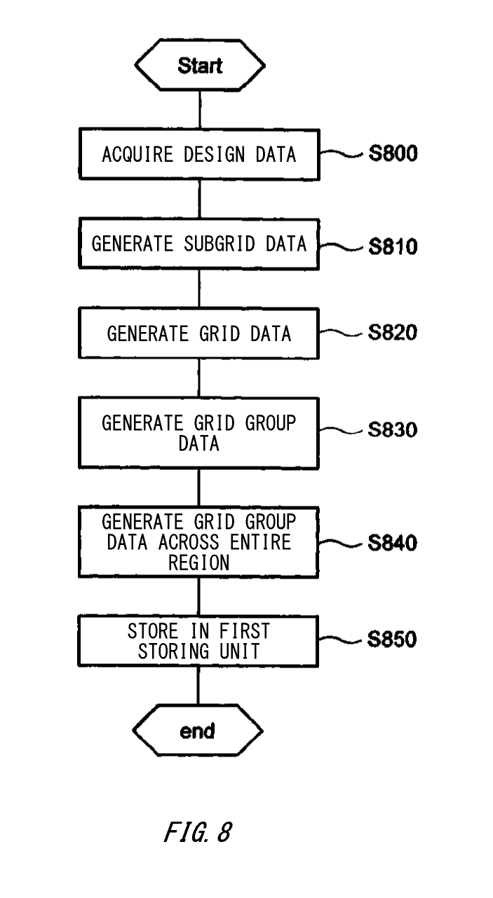

FIG. 8 is an example of a data conversion flow showing a method with which the converting unit 152 creates the exposure data 162 from the design data 150. The converting unit 152 creates the exposure data 162 based on the design data 150 by executing the data conversion flow from S800 to S850 shown in FIG. 8.

The converting unit 152 acquires the design data 150 in which the arrangement coordinate of the exposure pattern 610 is defined (S800). The converting unit 152 has the same width as a minimum width of the line pattern, and generates the subgrid data designating the arrangement coordinate of the pattern for each subgrid divided in the region with a fixed length in the X-axis direction being the second direction (S810). Next, the converting unit 152 generates the grid data designating, for each grid, the subgrid data belonging to the grids continuous in the X-axis direction being the second direction (S820).

Next, the converting unit 152 generates the grid group data designating the grid data for each grid group dividing the design data 150 in the grid group being the range of the predetermined length in the Y-axis direction (S830). Further, the converting unit 152 generates the grid group data across the entire area of the design data 150 in the Y-axis direction (S840). Finally, the converting unit 152 stores, in the first storing unit 160, the arrangement coordinate data of the cut pattern, and subgrid data, grid data and grid group data which hierarchically designate the arrangement coordinate data (S850).

The exposure data 162 stored in the first storing unit 160 has the first data 164 and the second data 166 which are converted from the design data 150 based on the first direction and the second direction controlling the exposure apparatus 100. In addition to the pattern data designating the arrangement coordinate of the individual exposure patterns 610, the exposure data 162 includes the subgrid data, grid data and grid group data which hierarchically designate the pattern data. The data capacity of the entire exposure data 162 is not so different from the data capacity of the design data 150, and the recent device 600 is 1 to 2 TB (terabytes), for example.

[Configuration Example of Beam Control Data 184 and Example of Method of Creating Beam Control Data 184]

Next, a configuration example of the beam control data 184 obtained by reconfiguring the exposure data 162 is described.

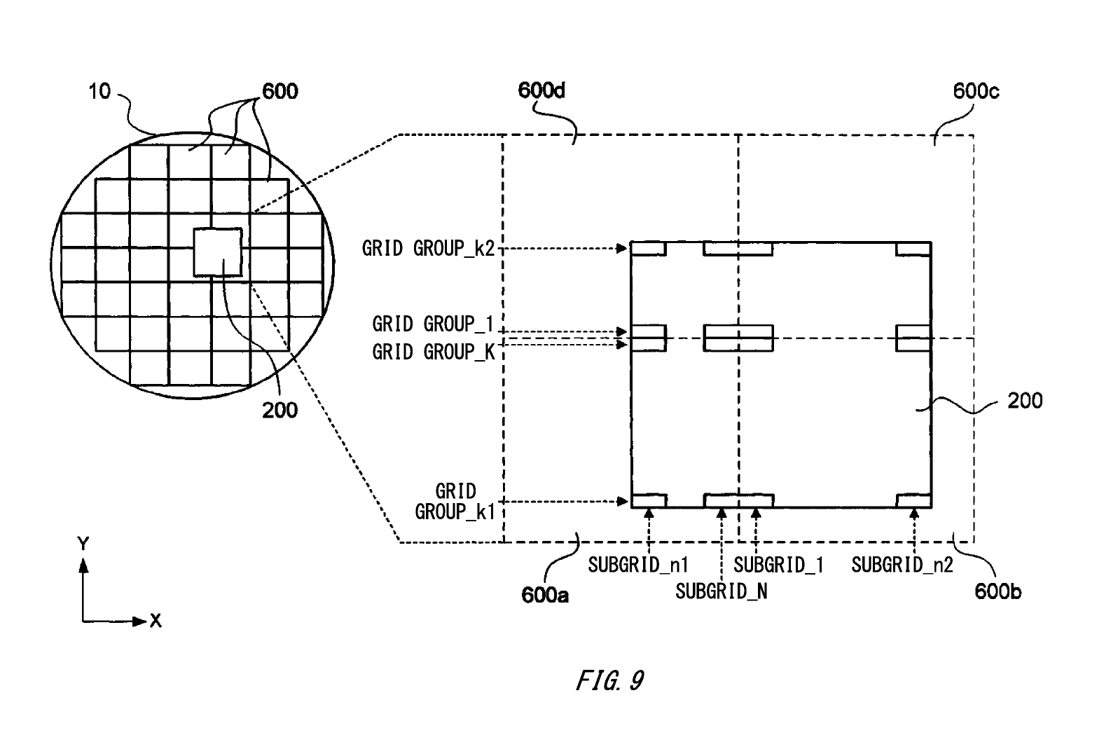

The round sample 10 of FIG. 9 shows an example that a plurality of devices 600 are exposed on the surface of the sample 10. It is assumed that the plurality of devices 600 all respectively have the same exposure pattern 610. The plurality of devices 600 are arranged on predetermined positions on the surface of the sample 10 in approximately parallel with the XY plane. The arrangement positions of the plurality of devices 600 on the surface of the sample 10 are determined based on the arrangement data 172 stored in the arrangement data storing unit 170 (refer to FIG. 1).

The region 200 of FIG. 9 shows one example of the irradiation possible region 200 (refer to FIG. 2) set on a part of the surface of the sample 10 corresponding to any column unit 120. The size of the irradiation possible region 200 in the X-axis direction is approximately 30 mm, and the size of the irradiation possible region 200 in the Y-axis direction is approximately 30 mm. In the exposure apparatus 100 having the plurality of column units 120, the irradiation possible regions 200 corresponding to each of the plurality of column units 120 occupy different regions on the surface of the sample 10. The surface of the sample 10 is covered by the irradiation possible regions 200 of the plurality of column units 120. It is assumed that the region 200 of FIG. 9 shows the irradiation possible region 200 for any one column unit 120.

The sizes of the irradiation possible region 200 in the X-axis direction and in the Y-axis direction may not match the sizes of device 600 in the X-axis direction and in the Y-axis direction. This is because that the size of the irradiation possible region 200 is determined depending on the interval between the adjacent column units 120, and the size of the device 600 is determined depending on the size of the designed device. Therefore, generally, the positions of four corners, i. e., upper, lower, right, and left corners of the irradiation possible region 200 are present within the device 600. Also, the relative positional relation between the irradiation possible region 200 of each of the plurality of column units 120 and the device 600 is different for each irradiation possible region 200.

The enlarged view surrounded by the dashed lines in FIG. 9 shows an example of the positional relation between the irradiation possible region 200 of any column unit 120 and the exposed device 600. An example is shown that in the irradiation possible region 200 of any column unit 120, the lower left, lower right, upper right, and upper left corners are respectively present within the devices 600 shown as reference signs 600a, 600b, 600c, and 600d. It is assumed that these devices 600 are referred to as the device 600a, device 600b, device 600c, and device 600d to distinguish them.

The exposure apparatus 100 exposes the irradiation possible region 200 by expanding the exposure range for each frame from the −Y side to the +Y side while reciprocating the array beam having the beam width of approximately 60 μm in the Y-axis direction along the frame in the X-axis direction. That is, in an initial frame, any column unit 120 starts the exposure at the inside of the lower left device 600a and ends the exposure in the inside of the lower right device 600b, for example. In a final frame, any column unit 120 starts the exposure at the inside of the upper right device 600c and ends the exposure in the inside of the upper left device 600d, for example.

In the middle of a frame, any column unit 120 crosses the boundary between the devices 600a and 600d on the left side and the boundary between the devices 600b and 600c on the right side. Also, during the exposure between the frames adjacent to each other vertically, any column unit 120 crosses the boundary between the devices 600a and 600b on the lower side and the boundary between the devices 600d and 600c on the upper side.

Based on FIG. 9, the corresponding relation between the exposure order and the exposure data 162 is described. The exposure data 162 has the first data 164 collected by the grid group unit in the Y-axis direction being the first direction which controls the exposure apparatus 100, and the second data 166 collected by the subgrid unit in the X-axis direction being the second direction which controls the exposure apparatus 100.

Gridgroup_k1, Gridgroup_K, Gridgroup_1, and Gridgroup_k2, and Subgrid_n1, Subgrid_N, Subgrid_1 and Subgrid_n2 shown in FIG. 9 show the grid groups in the Y-axis direction and the subgrids in the X-axis direction respectively corresponding to the four corners and the boundaries between the devices of the irradiation possible region 200 of any column unit 120.

In the initial frame, the beam control data 184 for any column unit 120 is created by reconfiguring the exposure data 162 as below. On the −X-side end of the initial frame, the beam control data 184 for any column unit 120 is configured with grid group data in the Y-axis direction extracted from the first data 164 and equivalent to the range of the beam width (frame width fw) of the array beam with Gridgroup_k1 as the lower end, and grid data designated by the grid group data. That is, for the Y-axis direction, the data overlapping the irradiation possible region 200 by the grid group unit is extracted.

Also, on the −X-side end of the initial frame, the beam control data 184 for any column unit 120 is configured with subgrid data in the X-axis direction extracted from the second data 166 within the frame being at the position equivalent to Subgrid_n1, and pattern data designated by the subgrid data. In this way, for the X-axis direction, the data overlapping the irradiation possible region 200 by the subgrid unit is extracted.

In accordance with the exposure progress in the initial frame, the beam control data 184 for any column unit 120 is configured with the first data 164 in the Y-axis direction, the first data 164 corresponding to the same grid group and the grid as those on the −X-side end of the frame. The beam control data 184 for any column unit 120 is configured with the second data 166, in the X-axis direction, the second data 166 corresponding to the subgrid and the pattern of the device 600 updated in accordance with the X-coordinate.

In the boundary between the devices 600a and 600b in the initial frame, the beam control data 184 for any column unit 120 is configured with the first data 164 in the Y-axis direction, the first data 164 corresponding to the same grid group and grid as those on the −X-side end of the frame. The beam control data 184 for any column unit 120 is configured so that the second data 166 corresponding to the subgrid and the pattern within the frame which is at the position equivalent to Subgrid_N on the right end of the device 600 switches to the second data 166, the second data 166 corresponding to the subgrid and the pattern within the frame which is at the position equivalent to Subgrid_1 on the left end of the device 600 in the X-axis direction.

On the +X-side end of the initial frame, the beam control data 184 for any column unit 120 is configured with the first data 164 in the Y-axis direction, the first data 164 corresponding to the same grid group and the grid as those on the −X-side end of the frame. The beam control data 184 for any column unit 120 is configured with the second data 166 in the X-axis direction, the second data 166 corresponding to the subgrid and the pattern within the frame which is at the position equivalent to Subgrid_n2 of the device 600.

Also, in the second and subsequent frames, the beam control data 184 for any column unit 120 is configured by extracting the exposure data included in the first data 164 by the grid group unit in the Y-axis direction in accordance with the exposure order according to the array beam and extracting the data included in the second data 166 by the subgrid unit in the X-axis direction.

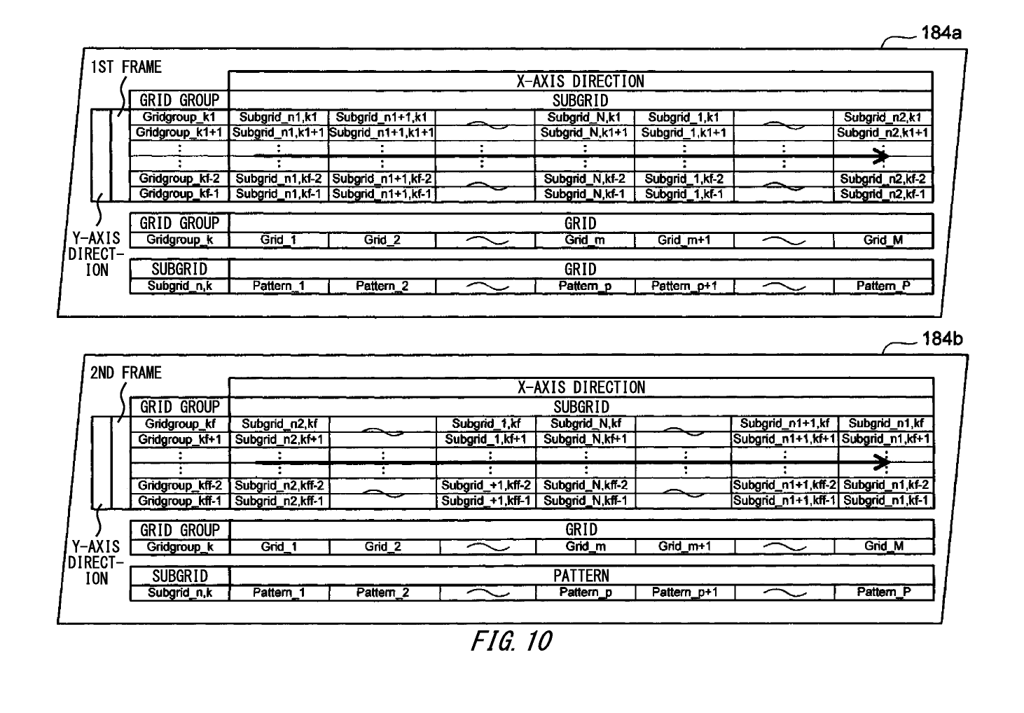

FIG. 10 shows a configuration example of the beam control data 184 according to the reconfiguration by extracting the data by the grid group unit and the subgrid unit from the first data 164 and the second data 166 in this way. Beam control data 184a is an example of the beam control data 184 for the first frame, and beam control data 184b is an example of the beam control data 184 for the second frame.

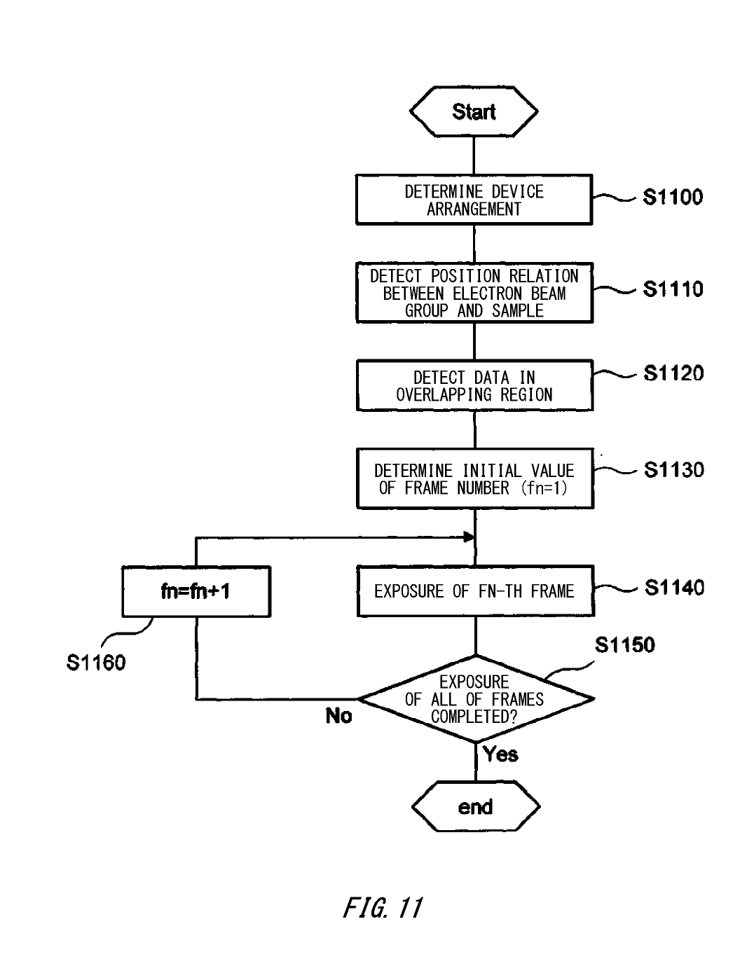

The Gridgroup, Grid, Subgrid, Pattern and the like respectively represent the grid group data, grid data, subgrid data, and pattern data included in the first data 164 and the second data 166. The terms such as X-axis direction, Y-axis direction, first frame, second frame, grid group, grid, subgrid, pattern, and the like are comments showing the contents of the data, and are not the data itself. FIG. 11 is also the same.

The beam control data 184a for the first frame of FIG. 10 is described. The first frame is configured with Gridgroup_k1 to Gridgroup_kf−1 included in the range of the beam width of the array beam with Gridgroup_k1 as the lower end. In this case, the beam control data 184a of the first frame has a plurality of grid group data, Gridgroup_k1 to Gridgroup_kf−1, in the Y-axis direction.

The beam control data 184a of the first frame also includes the data representing a designating/being designated relation between the grid group and the grid belonging to the first frame. Accordingly, the grid data designated by the grid group data, Gridgroup_k1 to Gridgroup_kf−1, is specified.

The beam control data 184a for the first frame has the subgrid data, Subgrid_n1, k1, Subgrid_n1+1, k1, . . . , and the like in the X-axis direction corresponding to the movement of the stage. Here, for example, the subgrid data, Subgrid_n1, k1, shows the n1-th subgrid data for the grid data designated by the data, Gridgroup_k1.

The thick line arrows in the drawing represent the beam control data 184 of the first frame configured with the subgrid data in the order of the thick line arrows. Also, the beam control data 184a of the first frame also includes the data representing the designating/being designated relation between the subgrid and the pattern in the range belonging to the first frame. Accordingly, the pattern data designated by the subgrid data, Subgrid_n1, k1, Subgrid_n1+1, k1, . . . , and the like, is specified for the grid data designated by the grid group data, Gridgroup_k1 to Gridgroup_kf−1.

The beam control data 184b of the second frame also has a similar configuration example. The beam control data 184b specifies the grid data in the Y-axis direction included in the second frame based on the grid group data, Gridgroup_kf to Gridgroup_kff−1, in the Y-axis direction. The beam control data 184b specifies the pattern data for each grid included in the second frame based on the subgrid data, Subgrid_n2, kf, Subgrid_n2−1, kf, . . . , and the like in the X-axis direction.

The order of the subgrid data shown by the thick line arrows for the beam control data 184a of the first frame is reverse to that of the beam control data 184b of the second frame. The above orders correspond to the exposure orders according to the movement of the stage portion 110 in the first frame and the second frame, which are reverse to each other in the X-axis direction. The configurations of the beam control data 184 in the third frame and subsequent frames are also similar to the above. The beam control data 184 may be created for each frame, and may be stored in the second storing unit 182 for each frame.

The relation between the irradiation possible region 200 and the beam control data 184 is further described. In the exposure apparatus 100 having the plurality of column units 120, the size of the irradiation possible region 200 may be set larger than the interval between the adjacent column units 120. This is because that parts of the irradiation possible regions 200 that the adjacent column units 120 are respectively in charge overlap with each other, and the entire surface of the sample 10 can be covered without an interval.

In this case, in order to configure the beam control data 184 for the overlapping regions of the irradiation possible regions 200, the first data 164 may be collected by the grid group unit of the region smaller than the overlapping region of the irradiation possible regions 200, and the second data 166 may be collected by the subgrid unit of the region smaller than the overlapping region of the irradiation possible regions 200. That is, the size of the grid group in the Y-axis direction and the size of the subgrid in the X-axis direction may be set as the size equal to or smaller than the width of the overlapping region of the irradiation possible regions 200 of the adjacent column units 120.

Accordingly, the beam control data 184 for the overlapping region of the irradiation possible regions 200 can be made by the grid group and the subgrid as the units, and the reconfiguration included in the beam control data 184 of either of the column units 120 can be performed. It is desirable that the size of the subgrid in the X-axis direction is set as 5 μm to 50 μm, for example. This is for setting the overlapping width of the irradiation possible regions 200 of the adjacent column units 120 in an appropriate range.

Also, the beam control data 184 depends on an angle between the scanning direction of the electron beam in the irradiation possible region 200 and the X-axis direction being the longitudinal direction of the line pattern, and the reconfiguration for the beam control data 184 in the Y-axis direction may be performed by the grid group unit. For the beam control data 184, the reconfiguration of switching the data of the grid group to the data of another grid group may be performed in the middle of a frame. Accordingly, even if the angle between the scanning direction of the electron beam and the X-axis direction being the longitudinal direction of the line pattern is large, the exposure from the right end to the left end of the irradiation possible region 200 can be performed with one frame.

It is desirable that the Y-axis direction width of the grid group is set as 1 μm to 10 μm, for example. This is for approximately matching the size of the grid group in the Y-axis direction to a deflection width of the array beam due to a deflector (not shown) included in the column unit 120. Even if a positional displacement between the Y-axis direction position of the array beam and the Y-axis direction position of the line pattern resulting from non-parallelism between the scanning direction of the electron beam and the longitudinal direction of the line pattern cannot be tracked due to the deflection caused by the deflector having a changing width of 1 μm to 10 μm, for example, the exposure apparatus 100 can expose from the right end to the left end of the irradiation possible region 200 with one frame by switching the data in the Y-axis direction by the grid group unit.

The data capacity of the beam control data 184 is approximately the same as the capacity of the design data 150 describing the exposure pattern 610 included in one frame. The data capacity of the beam control data 184 is 2 to 4 GB (gigabytes), for example. If one second storing unit 182 stores the beam control data 184 for two frames, the capacity of the data to be stored by the one second storing unit 182 is 4 to 8 GB, for example. The capacity of the data to be stored by the entire second storing unit 182 of the exposure apparatus 100 having 88 column units 120 is 350 to 700 GB, for example.

An example of a method with which the distributing unit 180 reconfigures the exposure data 162 to create the beam control data 184 is described.

FIG. 11 shows a part of the exposure flow that the exposure apparatus 100 exposes the sample 10 for each frame. FIG. 11 includes a flow that the distributing unit 180 reconfigures the exposure data extracted from the first data 164 and the second data 166 by each grid group unit and subgrid unit to create the beam control data 184. The distributing unit 180 distributes the beam control data 184 formed by reconfiguring the exposure data 162 to each column unit 120 during the flow shown in FIG. 11. The exposure apparatus 100 performs the exposure and the distribution of the beam control data 184 in parallel for each frame.

The exposure apparatus 100 reads the arrangement data 172 stored in the arrangement data storing unit 170 and determines the arrangement of the device 600 on the sample 10 (S1100). The exposure apparatus 100 measures the positional relation between the group of electron beams (array beam) generated by each of the column units 120 and the sample 10 by using a beam position detecting means such as a mark measurement (S1110).

For the first frame 232 (refer to FIG. 2) and the overlapping region of the first frame between the adjacent column units 120, the distributing unit 180 extracts, according to the order that the column unit 120 exposes on the first frame, the exposure data from the first data 164 by the grid group unit in the Y-axis direction being the first direction, and extracts the exposure data from the second data 166 by the subgrid unit in the X-axis direction being the second direction, and transfers, to the second storing unit 182, the exposure data along with the grid data and the pattern data designated by those data (S1120). The exposure apparatus 100 respectively sets initial values for exposure frame number fn and transfer frame number ft as fn←1 and ft←fn+1 (S1130).

The exposure apparatus 100 exposes on the fn-th frame. Concurrent with this, for the ft-th frame and the overlapping region of the ft-th frame between the adjacent column units 120, the distributing unit 180 extracts, according to the order that the column unit 120 exposes on the ft-th frame, the exposure data from the first data 164 by the grid group unit in the first direction, and extracts the exposure data from the second data 166 by the subgrid unit in the second direction, and transfers, to the second storing unit 182, the data of the ft-th frame along with the grid data and the pattern data (S1140).

The exposure apparatus 100 determines whether the exposure on all of the frames is completed or not (S1150). If the exposure on all of the frames is completed (S1150, Yes), the exposure apparatus 100 ends the exposure operation. If the exposure on all of the frames is not completed yet (S1150; No), the exposure apparatus 100 makes the stage movement to the starting point of a next frame, and respectively sets the exposure frame number fn and the transfer frame number ft as fn←fn+1, ft←fn+1 (S1160). The exposure apparatus 100 returns back to the step of exposing on the fn-th frame and transferring the data of the ft-th frame (S1140).

The distributing unit 180 performs the extraction of the exposure data, the creation of the beam control data according to the reconfiguration of the exposure data, and the data transfer to the second storing unit 182 during the frame exposure by the column unit 120. Because the first data 164 and the second data 166 are pre-created prior to the exposure, the distributing unit 180 may extract the data from the first data 164 and the second data 166 by the grid group unit and the subgrid unit, and perform the reconfiguration of the data and the data transfer in accordance with the exposure order for the extracted data. The rearrangement of the huge design data 150 is no longer necessary, and the exposure apparatus 100 can create the beam control data 184 according to the progress of the exposure.

Also, the distributing unit 180 can create the beam control data 184 even if the size of the device 600 to be exposed does not match the arrangement pitch of the column unit 120. This is because that the distributing unit 180 can also extract the exposure data from the first data 164 and the second data 166 by the grid group unit with the size of 1 μm to 10 μm and the subgrid unit with the size of 5 μm to 50 μm even if the boundary of the irradiation possible region 200 is within the exposed device 600.

[Configuration Example of History Data]

A configuration example of history data 194 is described.

The beam control data 184 is temporarily overwritten and saved in the second storing unit 182 for each frame. At the exposure ending time point, all of the beam control data 184 controlling the column units 120 is not left in the second storing unit 182.

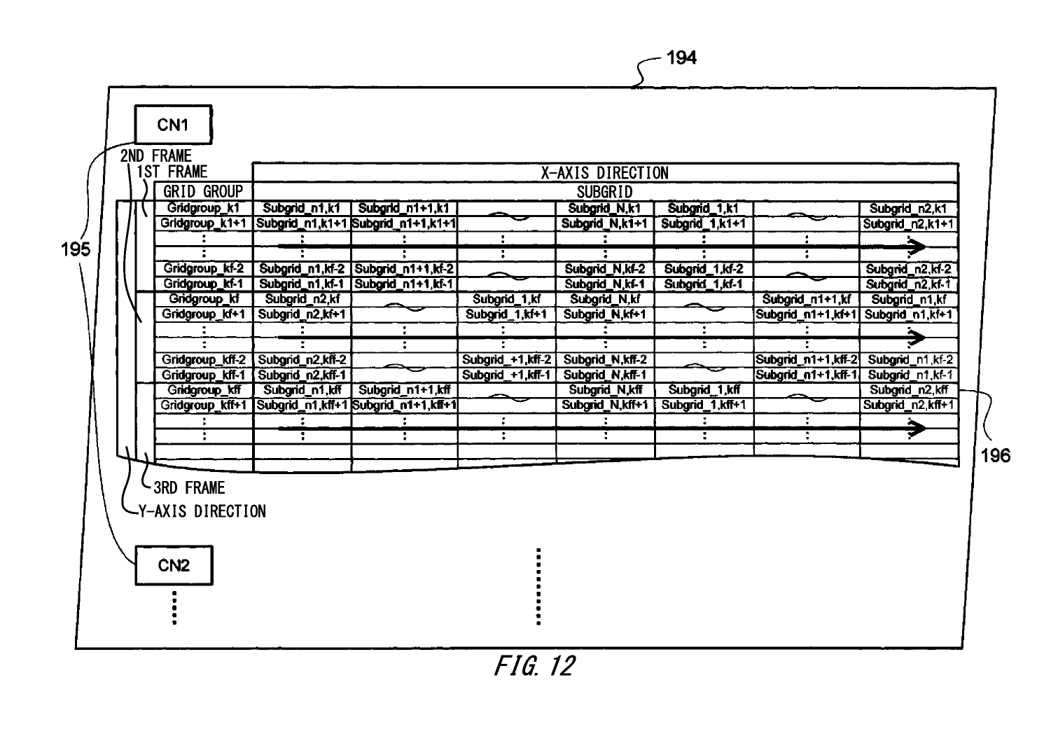

FIG. 12 is a configuration example of the history data 194 in which the beam control data 184 used for the exposure by the column units 120 is left as the history of the exposure order. The history data 194 includes only data 195 which distinguishes the column units 120, and grid group data and subgrid data 196 of the exposure orders of the respective column units 120.

The history data 194 of the column units 120 in which the data 195 is CN1 is described. The data 196 shows that the data designated by the grid group having the grid group data, Gridgroup_k1 to Gridgroup_kf−1, and the like is exposed in the first direction of the first frame. The data 196 shows that the pattern designated by the subgrid having the subgrid data, Subgrid_n1, k1, Subgrid_n1+1, k1, . . . , and the like is exposed in the direction shown by the thick line arrows in the second direction of the first frame.

Also, the data 196 shows that the data designated by the grid group having the grid group data, Gridgroup_kf to Gridgroup_kff−1, and the like is exposed in the first direction of the second frame. The data 196 shows that the pattern designated by the subgrid having the subgrid data, Subgrid_n2, kf, Subgrid_n2+1, kf, . . . , and the like is exposed in the direction shown by the thick line arrows in the second direction of the second frame.

The history data 194 associates the exposure pattern 610 on the sample 10 with the column unit 120 exposing the pattern and the exposure order of the column unit 120. That is, because the history data 194 is recording the grid group data and subgrid data 196 of the order in which the exposure has been performed, the exposure pattern 610 of each of the plurality of devices 600 formed in the sample 10 can know, after the exposure, the used column unit 120 and the exposure order in which the exposure has been performed by comparing with the original exposure data 162. This is because that as the grid group data and subgrid data 196 left in the history data 194 refers to the first data 164 which shows the relation between those grid group data, and the second data 166 which shows the relation between the subgrid data and the pattern, the exposure pattern 610 which has been designated can be tracked.

The history data 194 provides useful information for the inspection of the exposure pattern 610 after the exposure. Because the history data 194 is only the grid group data and subgrid data 196, its data capacity is 50 to 100 MB (megabytes), for example. The data capacity of the history data 194 is sufficiently small compared to the data capacity of the exposure data 162.

The history data 194 stores not only the grid group data and subgrid data 196 arranged in the exposure order, but may also store the data related to the state of the column units 120. The data related to the state of the column units 120 is data related to a current density of an electron beam generated by each of the column units 120, the beam size, and/or an imaging state of the beam, and the like, for example. The data related to the state of the column units 120 may be detected periodically when switching the frames between the respective frame exposures. Accordingly, the history data 194 provides the information further useful for the inspection of the exposure pattern 610.

The above-described various embodiments of the present invention may be described referring to flow charts and block diagrams. A block in the flow charts and the block diagrams may be expressed as (1) a step of a process that an operation is executed, or (2) a “unit/portion” of an apparatus serving a function of executing the operation. A specified step and “unit/portion” may be implemented by a dedicated circuit, a programmable circuit supplied together with a computer readable instruction stored on a computer readable storage medium, and/or a processor supplied together with the computer readable instruction stored on the computer readable storage medium.

A specified step and “unit/portion” may be implemented by a dedicated circuit, a programmable circuit supplied together with a computer readable instruction stored on a computer readable storage medium, and/or a processor supplied together with the computer readable instruction stored on the computer readable storage medium. Note that the dedicated circuit may include a digital and/or analog hardware circuit, and may include an integrated circuit (IC) and/or a discrete circuit. The programmable circuit may include a reconfigurable hardware circuit including logical product, logical disjunction, exclusive logical disjunction, negative logical product, negative logical disjunction, and other logic operations, a flip flop, a register, and a memory element, such as Field Programmable Gate Array (FPGA), Programmable Logic Array (PLA), and the like, for example.

The computer readable storage medium may include any tangible device which can store an instruction executed by an appropriate device. Accordingly, the computer readable storage medium having the instruction stored in the tangible device includes a product including an instruction which may be executed to create a means for executing an operation designated in the flow charts or block diagrams.

As an example of the computer readable storage medium, an electron storage medium, a magnetic storage medium, an optical storage medium, an electromagnetic storage medium, a semiconductor storage medium, and the like may be included. As a further specific example of the computer readable storage medium, a Floppy (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact discrete read-only memory (CD-ROM), a digital versatile disk (DVD), a Blu-ray (registered trademark) disk, a memory disk, an integrated circuit card, and the like may be included.

The computer readable instruction may include an assembler instruction, an instruction set architecture (ISA) instruction, a machine instruction, a machine-dependent instruction, a microcode, a firmware instruction, a state-setting data, and the like. Also, the computer readable instruction may include a source code or an object code described by any combination of one or more programming languages including conventional procedural programming languages such as an object-oriented programming language, such as Small talk, JAVA (registered trademark) and C++, and “C” programming language or a similar programming language.

The computer readable instruction may be provided in a general-purpose computer, a special-purpose computer, or a processor of another programmable data processing apparatus, or a programmable circuit locally or via a local area network (LAN), a wild area network (WAN) such as Internet, or the like. Accordingly, the general-purpose computer, the special-purpose computer, or the processor of the other programmable data processing apparatus, or the programmable circuit can execute the computer readable instruction in order to generate a means for executing an operation designated in the flow charts or block diagrams. Note that as an example of the processor, a computer processor, a processing unit, a microprocessor, a digital signal processor, a controller, a micro controller, and the like are included.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. An exposure apparatus to form a cut pattern on a sample on which a line pattern is formed, the exposure apparatus comprising:
a column unit to generate a first group of charged particle beams arrayed in a row at fixed intervals in a first direction, and a second group of charged particle beams arranged in parallel with and adjacent to the first group of charged particle beams and arranged with the same size and in the same pitch as those of the first group of charged particle beams;
a column control unit to separately control an irradiation timing of each charged particle beam included in the first group of charged particle beams and in the second group of charged particle beams;
a converting unit to convert design data describing an arrangement coordinate of device patterns formed on the sample as a base into exposure data, the exposure data including second data formed by dividing into belt-like regions which extend in a second direction and have a width of one charged particle beam, and first data specifying the second data based on a position of a first direction;
a first storing unit to store the exposure data; and
a distributing unit to create beam control data for the column unit by reconfiguring the exposure data including the first data and the second data in accordance with an order in which the column unit exposes on the sample based on a relative positional relation between a position of the sample on a stage and the column unit.

2. The exposure apparatus according to claim 1, further comprising:
a plurality of the column units, wherein the column units adjacent to each other respectively have irradiation possible regions in charge, parts of the radiation possible regions overlapped with each other.

3. The exposure apparatus according to claim 1, wherein
the first data is collected by a unit of a grid group having a size smaller than an overlapping region width of the irradiation possible regions of the column units in a first direction, and the second data is collected per subgrid having a size smaller than the overlapping region width of the irradiation possible regions of the column units in a second direction.

4. The exposure apparatus according to claim 3, wherein
the distributing unit creates the beam control data for each column unit by reconfiguring the first data by the unit of the grid group and reconfiguring the second data by the unit of the subgrid based on the positional relation between the column unit and the sample.

5. The exposure apparatus according to claim 3, comprising:
a second storing unit which is provided in each of the column units and temporarily stores the beam control data distributed by the distributing unit.

6. The exposure apparatus according to claim 5, wherein
the second storing unit includes at least two storing portions, wherein
one of the storing portions temporarily stores the beam control data in a region which is to be exposed due to one movement of the sample toward the second direction during exposure, and performs the exposure, and the other one of the storing portions reads the beam control data of a region which is to be exposed due to a next movement toward the second direction.

7. The exposure apparatus according to claim 3, comprising:
a collecting unit to collect history data consisting of data of the grid group and of the subgrid corresponding to each of the column units in an order in which the column units perform the exposure; and
a third storing unit to store the history data for all of the column units.

8. A non-transitory storage medium readable by a computer, the non-transitory storage medium recording an exposure data structure for an exposure apparatus which irradiates a plurality of groups of charged particle beams arrayed in a first direction orthogonal to a longitudinal direction of a line pattern to form a cut pattern while moving a sample in a second direction being the longitudinal direction of the line pattern formed in advance on the sample, wherein
the exposure data structure is configured with:
subgrid data to designate an arrangement coordinate of patterns included in a subgrid having a fixed length in the second direction among patterns included in grids which have the same width as a minimum width of the line pattern and extend in the second direction,
grid data to designate the subgrid data included in one piece of the grid, and
grid group data to designate grid data belonging to a grid group divided for each fixed range in the first direction.

9. A non-transitory storage medium readable by a computer, the non-transitory storage medium recording the exposure data structure according to claim 8, wherein
a size of the subgrid in the second direction and a size of the grid group in the first direction are set as a size equal to or less than a width of overlapping regions of irradiation possible regions of adjacent columns.

10. An exposure data creating method for an exposure apparatus which irradiates a plurality of groups of charged particle beams arrayed in a first direction orthogonal to a longitudinal direction of a line pattern to form a cut pattern while moving a sample in a second direction being the longitudinal direction of the line pattern formed in advance on the sample, the exposure data creating method comprising:
generating, in a converting unit, subgrid data which designates an arrangement coordinate of cut patterns for each of subgrids by acquiring design data with a defined pattern arrangement and dividing the design data into the subgrids which are regions having the same width as a minimum width of the line pattern and having a fixed length in the second direction;
generating, in the converting unit, grid data which designates, for each of grids, subgrid data belonging to the grids continuous in the second direction;
generating, in the converting unit, grid group data designating, for each grid group, grid data belonging to a grid group which divides the design data for each predetermined length range in the first direction;
generating, in the converting unit, grid group data across an entire area of the design data in the first direction; and
storing, in a first storing unit, the subgrid data, the grid data, and the grid group data.

11. A beam control data creating method, comprising:
determining an arrangement of exposure data on a sample by reading arrangement data stored in an arrangement data storing unit;
measuring a positional relation between a group of charged particle beams generated by a column unit and the sample; and
extracting, by a distributing unit, exposure data for a region on which the column unit performs exposure due to one stage movement toward a second direction, and reconfiguring the exposure data as beam control data in accordance with an order in which the column unit performs the exposure.

12. The beam control data creating method according to claim 11, comprising: extracting, by the distributing unit, first data by a grid group data unit for a first direction among the exposure data, extracting second data by a subgrid data unit for the second direction, and reconfiguring the exposure data in a range of which the column unit is in charge.
